(19) United States
(12) Patent Application Publication
(10) Pub. No.: US 2025/0253232 A1
(43) Pub. Date: Aug. 7, 2025

(54) MANUFACTURING METHOD OF AN ELECTRONIC CHIP INCLUDING A MEMORY CIRCUIT

(71) Applicant: STMicroelectronics International N.V., Geneva (CH)

(72) Inventors: Luca LAURIN, Lissone (IT); Christian BOCCACCIO, Bernin (FR); Simon JEANNOT, Grenoble (FR); Jury SANDRINI, Grenoble (FR)

(73) Assignee: STMicroelectronics International N.V., Geneva (CH)

(21) Appl. No.: 19/003,911

(22) Filed: Dec. 27, 2024

(30) Foreign Application Priority Data
Jan. 2, 2024 (FR) FR2400015

(51) Int. Cl. H01L 23/522; H10B 63/10

(52) U.S. Cl. CPC H01L 23/5226; H10B 63/10

(57) ABSTRACT

An electronic chip includes a memory circuit including: a semiconductor substrate having selection transistors arranged therein and an interconnection stack arranged on the semiconductor substrate. The interconnection stack includes a succession of levels, each level including a first insulating layer and a second insulating layer having interconnection elements defined therein. The memory circuit includes a plurality of memory cells arranged above the interconnection stack. Each memory cell is adapted to be electrically coupled to a selection transistor via a first conductive via running through the entire thickness of the interconnection stack.

### CROSS-REFERENCE TO RELATED APPLICATION(S)

The present application is based on, and claims priority from, French patent application 2400015, filed on Jan. 2, 2024, entitled “Procédé de fabrication d'une puce électronique comprenant un circuit mémoire,” which is incorporated by reference to the extent permitted by law.

### BACKGROUND

### Technical Field

The present disclosure generally concerns the field of electronic chips and more particularly the field of electronic chips including a memory circuit based on a phase-change material and their manufacturing methods.

### Description of the Related Art

A phase-change material is a material having the ability to change crystalline state under the effect of heat, and more specifically to switch between a crystalline state and an amorphous state, more highly resistive than the crystalline state. This phenomenon is used to define two memory states, for example 0 and 1, differentiated by the resistance measured through the phase-change material.

There exists a need to improve electronic chips including a memory circuit including memory cells based on a phase-change material, and their manufacturing methods.

### BRIEF SUMMARY

In one embodiment, an electronic chip includes a memory circuit including:
a semiconductor substrate having selection transistors arranged therein;
an interconnection stack, arranged on the semiconductor substrate, including a succession of levels, each level including a first insulating layer and a second insulating layer, having interconnection elements defined therein; and—a plurality of memory cells arranged above the interconnection stack, each memory cell being adapted to being electrically coupled to a selection transistor via a first conductive via running through the entire thickness of the interconnection stack.

According to an embodiment, the semiconductor substrate includes, from an upper surface, a first doped semiconductor layer of a first conductivity type, located on top of and in contact with a second doped semiconductor layer of a second conductivity type opposite to the first conductivity type.

According to an embodiment, the semiconductor substrate is topped with a third semiconductor layer including first doped regions of the second conductivity type, each of the first regions of the third semiconductor layer being coupled to a memory cell via the first conductive via.

According to an embodiment, the first semiconductor layer, the second semiconductor layer, and the first regions of the third semiconductor layer form the selection transistors.

According to an embodiment, the third semiconductor layer includes second doped regions of the first conductivity type, each of the second regions of the third semiconductor layer being coupled to a set of second conductive vias and of conductive tracks crossing the interconnection stack.

According to an embodiment, the second conductive vias and the conductive tracks are made of copper.

According to an embodiment, the conductive tracks extend laterally over a surface area greater than the surface area of the first conductive via.

According to an embodiment, at least two second regions are coupled to each other by a set of second conductive vias and of conductive tracks located in the interconnection stack between the substrate and the memory cells.

According to an embodiment, the chip includes dummy memory cells located in front of the second regions.

According to an embodiment, the first conductive via is made of a metallic material.

According to an embodiment, the first conductive via is made of tungsten, of cobalt, or of copper.

An embodiment provides a method of manufacturing an electronic chip including a memory circuit including the following successive steps:
a) forming selection transistors in a semiconductor substrate;
b) forming an interconnection stack, arranged on the semiconductor substrate, including a succession of levels, each level including an alternation of first insulating layers and of second insulating layers having interconnection elements defined therein; and
c) forming a plurality of memory cells arranged above the interconnection stack, each memory cell being electrically coupled to a selection transistor via a first conductive via running through the entire thickness of the interconnection stack.

According to an embodiment, the first conductive via is formed between steps b) and c).

According to an embodiment, the step of forming of the first conductive vias includes a step of etching of the interconnection stack so as to form openings and a step of filling of the openings.

According to an embodiment, the step of etching of the interconnection stack corresponds to a step of etching of all the first insulating layers and of second insulating layers of the interconnection stack.

In one embodiment, a method includes forming a plurality of selection transistors, forming a first pair of dielectric layers above the selection transistors, and forming a second pair of dielectric layers above the first pair of dielectric layers. The method includes forming a metal interconnect structure extending through the first and second pairs of dielectric layers and electrically coupled to a first selection transistor of the plurality of selection transistors. The method includes forming, after forming the metal interconnect structure, a first conductive via extending through the first and second pairs of dielectric layers and electrically coupled to a second selection transistor of the plurality of selection transistors. The method includes forming a first memory cell on the conductive via.

### BRIEF DESCRIPTION OF THE SEVERAL VIEWS OF THE DRAWINGS

The foregoing features and advantages, as well as others, will be described in detail in the rest of the disclosure of specific embodiments given as an illustration and not limitation with reference to the accompanying drawings, in which:

FIG. 1A and FIG. 1B illustrate two cross-section views, partial and simplified, of an electronic chip according to an embodiment;

FIGS. 2A-2S show steps of an example of a method of manufacturing the electronic chip illustrated in FIGS. 1A and 1n FIG. 1B, according to an embodiment; and

FIG. 3 shows a cross-section view, partial and simplified, of an electronic chip according to another embodiment.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front,” “back,” “top,” “bottom,” “left,” “right,” etc., or relative position qualifiers, such as “top,” “bottom,” “upper,” “lower,” etc., or orientation qualifiers, such as “horizontal,” “vertical,” etc., reference is made unless otherwise specified to the orientation of the drawings.

Unless specified otherwise, the expressions “about,” “approximately,” “substantially,” and “in the order of” signify plus or minus 10%, preferably of plus or minus 5%.

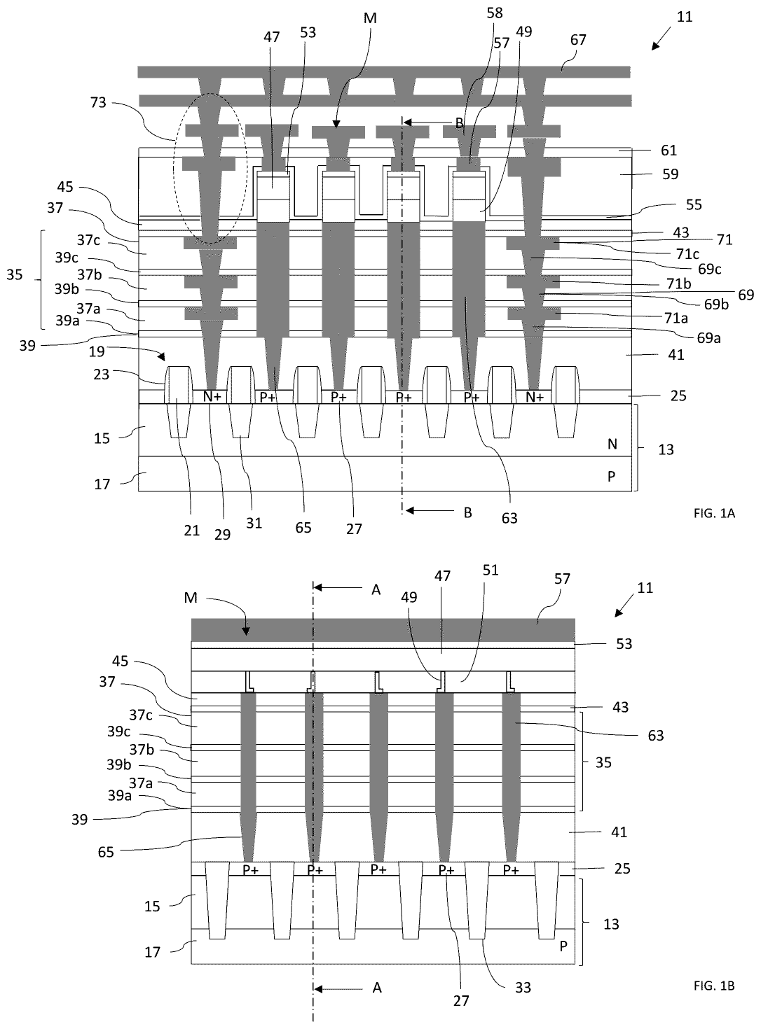

FIG. 1A and FIG. 1B illustrate two cross-section views, partial and simplified, of an electronic device, for example of an electronic chip 11 according to an embodiment, FIG. 1A being a view along the cross-section plane AA of FIG. 1B and FIG. 1B being a view along the cross-section plane BB of FIG. 1A.

More particularly, FIG. 1A and FIG. 1B illustrate a portion of a memory circuit of electronic chip 11. As an example, electronic chip 11 includes, in a portion not shown, a logic circuit adjacent to the memory circuit. The logic and memory circuits are, for example, manufactured simultaneously inside and on top of a same semiconductor substrate.

The electronic chip includes a semiconductor substrate 13. As an example, substrate 13 is made of silicon or based on silicon.

Substrate 13 includes, for example, a doped semiconductor layer 15 of a first conductivity type, for example of type N, for example doped with arsenic or phosphorus atoms. Layer 15 rests, for example, on another semiconductor layer 17 of substrate 13 doped with a second conductivity type, opposite to the first conductivity type, for example of type P, for example doped with boron atoms.

As an example, chip 11 includes gate patterns 19 arranged on the upper surface of layer 15, for example extending longitudinally in a first direction. Gate patterns 19 include, for example, a central portion 21 laterally surrounded by spacers 23. The central portion 21 of each gate pattern 19 is, for example, made of a semiconductor material, for example of silicon, for example of polysilicon. Spacers 23 are made of an electrically-insulating material, such as silicon nitride.

Gate patterns 19 are, for example, laterally separated by a semiconductor layer 25, for example formed by epitaxy from the upper surface of layer 15. Layer 25 is made of silicon, for example of single-crystal silicon.

Layer 25 includes, for example, first regions 27, for example doped with the second conductivity type, for example type P, and extending between certain gate patterns 19. Regions 27 are, for example, more heavily doped than layer 17. Each region 27 is, for example, topped with a memory cell M.

Memory cells M are for example organized, in top view, in an array of rows and columns. It is respectively spoken of word lines and of bit lines, each M memory cell being located at the intersection of a bit line and of a word line. As an example, the memory cells M illustrated in FIG. 1A are memory cells M of a same word line, while the memory cells illustrated in FIG. 1B are memory cells of a same bit line. In the example of FIG. 1A, gate patterns 19 extend in the same direction as the memory cells M of FIG. 1A, that is, in the bit line direction. In this example, gate patterns 19 extend, in top view, between the regions 27 of layer 25. In other words, in this example, in top view, any two consecutive regions 27 are separated from each other by one and only one gate pattern 19 extending along the entire length of the bit lines. In FIG. 1A, only four bit lines are shown and in FIG. 1B, only five word lines are shown. However, in practice, in one embodiment a memory circuit includes a number of bit lines and of word lines respectively different from four and five, for example greater than four and five.

Layer 25 further includes second regions 29, for example doped with the first conductivity type, for example, type N, and extending between other gate patterns 19. Regions 29 are, for example, more heavily doped than layer 15. Regions 29, unlike regions 27, are not topped with memory cells M.

Regions 29 and 27 are, for example, laterally delimited, in the word line direction, by gate patterns 19 and by first insulating trenches 31, for example super shallow trench isolation (SSTI) trenches. The first insulating trenches 31 prevent, for example, electric current leakages between two successive bit lines. The first trenches 31 are located, for example, under gate patterns 19. As an example, the first trenches 31 are linear and each gate pattern 19 is located on top of and in contact with a first trench 31. As an example, each first trench 31 extends longitudinally in the bit line direction, along the entire length of the bit lines. As an example, the first trenches 31 extend, vertically, in layer 15, from the upper surface of layer 15 across only part of the thickness of layer 15. The first insulating trenches 31 are, for example, filled with a dielectric material, for example silicon oxide. The depth of the first trenches 31 is, for example, in the range from 20 nm to 40 nm.

As an example, chip 11 includes second insulating trenches 33, for example shallow trench isolation (STI) trenches. Insulating trenches 31 and insulating trenches 33 are, for example, orthogonal and form a gate. The depth of insulating trenches 33 is, for example, greater than the depth of insulating trenches 31. Insulating trenches 33 extend, for example, from the upper surface of layer 15, in layer 15 and in part of layer 17. As an example, insulating trenches 33 enable to separate and thus to electrically insulate strips of layer 15 respectively vertically in line with each word line. As an example, each insulating trench 33 extends longitudinally in the word line direction, along the entire length of the word lines. Insulating trenches 33 are for example filled with a dielectric material, for example silicon oxide. The depth of trenches 33 is, for example, in the range from 300 nm to 400 nm.

In the example of FIGS. 1A and 1B, the structure formed by layers 15, 17, and 21 and gate patterns 19 is topped with an interconnection stack 35. In this example, interconnection stack 35 is formed between substrate 13 and memory cells M. Interconnection stack 35 is for example formed by a succession of levels, each level including an insulating layer 37 and an insulating layer 39.

Interconnection stack 35 is for example formed on an insulating layer 41 covering the upper surface of layer 25 and the upper surface of gate pattern 19. Insulating layer 41 is, for example, in contact with the upper surface of layer 25 and the upper surface of gate patterns 19. Insulating layer 41 for example covers the entire upper surface of layer 25. Insulating layer 41 has a thickness in the range from 100 nm to 500 nm, for example in the range from 120 nm to 160 nm.

Interconnection stack 35 is, for example, formed on the upper surface of insulating layer 41 and covers, for example, the entire surface of insulating layer 41. Interconnection stack 35 includes, for example, an insulating layer 39a formed on top of and in contact with the upper surface of insulating layer 41. Interconnection stack 35 further includes an insulating layer 37a formed on insulating layer 39a. Insulating layer 37a is for example formed over the entire surface of insulating layer 39a. As an example, insulating layer 37a is in contact, by its lower surface, with the upper surface of insulating layer 39a. Layers 39a and 37a form a level of the interconnection stack.

In one embodiment, the interconnection stack 35 further includes additional levels formed on top of and in contact with insulating layer 37a. In FIGS. 1A and 1B, interconnection stack 35 includes two additional levels, for example respectively formed by layers 37b and 39b and layers 37c and 39c. In practice, in one embodiment, the number of levels in interconnection stack 35 is different from three, for example greater than or equal to one.

As an example, interconnection stack 35 has a thickness in the range from 100 nm to 600 nm, for example in the range from 200 nm to 500 nm, for example in the order of 300 nm.

Interconnection stack 35 is for example topped with an insulating layer 43. Insulating layer 43 is for example formed on top of and in contact with interconnection stack 35 and more particularly on top of and in contact with insulating layer 37c. Insulating layer 43 extends, for example, over the entire surface of interconnection stack 35.

As an example, insulating layers 41 and 37 are made of a material having a low dielectric constant, for example made of a material having a dielectric constant (corresponding to the permittivity of the material relative to the permittivity of vacuum) smaller than 5, for example smaller than 4. Insulating layers 37 are for example made of SiOC, of porous SiOC, of SiOCH, or of porous SiOCH. As an example, insulating layers 39 and 43 are made of silicon carbonitride (SiCN), of silicon nitride, of SiCH or of SiNHC, or of porous SiCN.

Insulating layer 43 is for example topped with an insulating layer 45. Insulating layer 45 is for example made of a material having a low dielectric constant, or of silicon dioxide (SiO₂). As an example, insulating layer 45 is formed on top of and in contact with the upper surface of insulating layer 43.

Memory cells M are, in this embodiment, are formed on the upper surface of insulating layer 45.

As an example, memory cells M are based on a phase-change material in a layer 47, for example based on a chalcogenide material, for example an alloy of germanium, antimony, and telluride (GeSbTe) called GST. The phase-change material has, for example, a thickness in the range from 30 nm to 100 nm, for example in the order of 50 nm.

In each memory cell M, the phase-change material is, for example, controlled by a metallic resistive heating element 49 located under the phase-change material, for example in contact, by its upper surface, with the lower surface of layer 47 of the phase-change material, and laterally surrounded with a layer made of a thermal insulator 51. For example, each element 49 has an L shape in the cross-section plane of FIG. 1B. Each element 49 for example includes a horizontal portion extending over the upper surface of the corresponding via 63 and a vertical portion extending from via 63 to layer 47. As an example, layer 51 is made of silicon carbonitride. As an example, layer 51 includes a plurality of insulating materials. As an example, heating element 49 has a thickness in the range from 30 nm to 170 nm, for example in the order of 80 nm.

Layer 47 of phase-change material is, for example, topped with metal elements, or metallizations, 53. As an example, in each memory cell M, metal elements 49 and 53 respectively form a lower electrode and an upper electrode of the variable-resistance resistive element formed by layer 47 of the phase-change material. As an example, the memory cells M of a same bit line are topped with a same metallization 53. In other words, the upper electrodes 53 of the memory cells M of a same bit line are interconnected.

Each memory cell M is for example covered with an insulating layer 55 protecting layer 47 of phase-change material from oxidation. Insulating layer 55 is made of a nitride, for example of silicon nitride. Each memory cell M is further topped with a metal contact 57 extending, for example, over metallization 53. Metal contacts 57 are for example made of copper.

The memory cells M of adjacent bit lines are for example insulated from one another by an insulating layer 59. Insulating layer 59 is for example made of a material having a low dielectric constant. As a variant, layer 59 is made of an oxide, for example, of silicon dioxide.

Each contact 57 preferably extends from the upper surface of metal element 53 to the upper surface of layer 59. Thus, each contact 57 crosses layer 55 to reach the metal element 53 of the corresponding cell. The upper surface of each element 57 is thus coplanar with the upper surface of layer 59.

Similar to what has been described for metallizations 53, the contacts 57 of the memory cells M of the same bit line are interconnected. Contacts 57 are for example coupled to one another in layer 59. Alternatively, each contact 57 is coupled to a set of conductive vias and of conductive tracks 58 located in a level of an interconnection network resting on layer 59.

Layer 59 is for example topped with a conductive layer 61. Conductive layer 61 is for example made of silicon nitride or of silicon carbonitride. Layer 61 and layers not shown, are for example, in the interconnection network resting on layer 59.

In the example of FIGS. 1A and 1B, for each memory cell M, the region 27 located vertically in line with memory cell M, layer 15 (and region 29) and layer 17 define a bipolar transistor, here of PNP type, for selecting the memory cell. For example, each memory cell M is associated with a bipolar transistor. In this example, region 27 forms an emitter region of the transistor, region 15 (and region 29) forms a base region of the transistor, and layer 17 forms a collector region of the transistor. As an example, the collector is common to all the transistors in the array and is, for example, connected to ground. In this example, base region 15 is common to all the transistors of a same word line of the memory circuit.

Each memory cell M is electrically connected to the selection transistor with which it is associated via a conductive via 63 running through the entire thickness of interconnection stack 35. As an example, via 63 runs through all the insulating layers 37 and 39 of interconnection stack 35. The via 63 is a conducting via, it is not composed of a succession of conducting vias and conducting tracks.

As an example, via 63 is in contact, by its upper surface, with the lower surface of the resistive heating element 49 of memory cell M. Via 63 is for example in contact, by its lower surface, with another conductive via 65, itself in contact with the upper surface of layer 25.

As an example, for each memory cell M, the corresponding via 63 electrically couples the heating element 49 of the memory cell to the underlying region 27.

Conductive via 63 is for example made of a metallic material. Conductive via 63 is for example made of tungsten. As a variant, conductive via is made of cobalt or of copper. Conductive via 63 has, for example, a width, taken in the plane of FIG. 1A and in the plane of FIG. 1B, in the range from 40 nm to 100 nm, for example in the order of 70 nm.

Conductive via 65 for example crosses insulating layer 41. Conductive via 65 is flush, for example, by its lower surface, with the lower surface of insulating layer 41, and by its upper surface, with the upper surface of insulating layer 41. Conductive via 65 is for example in contact, by its lower surface, with the upper surface of layer 25 and more particularly with region 27. Conductive via 65 is for example in contact, by its upper surface, with the lower surface of conductive via 63. Conductive via 65 is for example made of a metallic material, for example of tungsten.

The second regions 29 of layer 25 are for example coupled to metal contacts 67. Metal contacts 67 are for example made of copper. Contacts 67 for example correspond to the contacting areas of the word lines. Contacts 67 correspond, for example, to conductive tracks of the interconnection network extending over layer 59.

As an example, each region 29 is coupled to a contact 67 by the succession of vias and of conductive tracks successively running through insulating layer 41, interconnection stack 35, conductive layer 43, insulating layer 45, layer 55, insulating layer 59, and layer 61. As an example, each region 29 is topped with a conductive via 65 running through insulating layer 41, similarly to what has been described vertically in line with regions 27. As an example, each via 65 topping a region 29 is topped with an alternation of vias 69 and of conductive tracks 71.

A via 69a for example runs through a portion of insulating layer 37a, and a conductive track 71a contacts via 69a to via 65. As an example, via 69a is flush by its lower surface with the lower surface of insulating layer 39a. As an example, via 69a is in contact by its upper surface with the lower surface of conductive track 71a. Conductive track 71a is flush, for example by its upper surface, with the upper surface of insulating layer 37a.

Similarly, layers 37b and 39b are for example crossed by a via 69b and a conductive track 71b, and layers 37c and 39c are crossed by a via 69c and a conductive track 71c. As an example, the upper conductive track 71 of interconnection stack 35, here conductive track 71c, is connected to contact 67 by a set 73 of conductive vias and of conductive tracks. Contacts 57 correspond, for example, to conductive tracks located in layer 59, such as the conductive tracks allowing the connection between regions 29 and contacts 67.

Conductive vias and tracks 71 and 69 are for example made of a metallic material, for example of copper. As an example, conductive tracks 71 laterally extend over a surface area in the range from 60 nm by 60 nm and 100 nm by 100 nm, for example in the order of 80 nm by 80 nm. As an example, conductive tracks 71 laterally extend over a surface area greater than the surface area of vias 69 and of conductive via 63. An advantage of connecting each memory cell M to a via 63 and not to a conductive track 71 is that this enables to do away with metal level sizing constraints for the integration of PCM cells.

As an example, the interconnection stack 35 extends into the portion of the device containing the memory cells and into the portion of the device containing the logic circuits. Advantageously, the interconnection stack 35 does not include, in the portion of the device comprising the logic circuits, vias 63, that is vias crossing the entire height of the interconnection stack 35. Thus, in the portion of the device containing the logic circuits, each level of the interconnection stack 35 includes vias and conductive tracks and does not include a via alone. An advantage of the described configuration is that it does not limit the performance of the logical part.

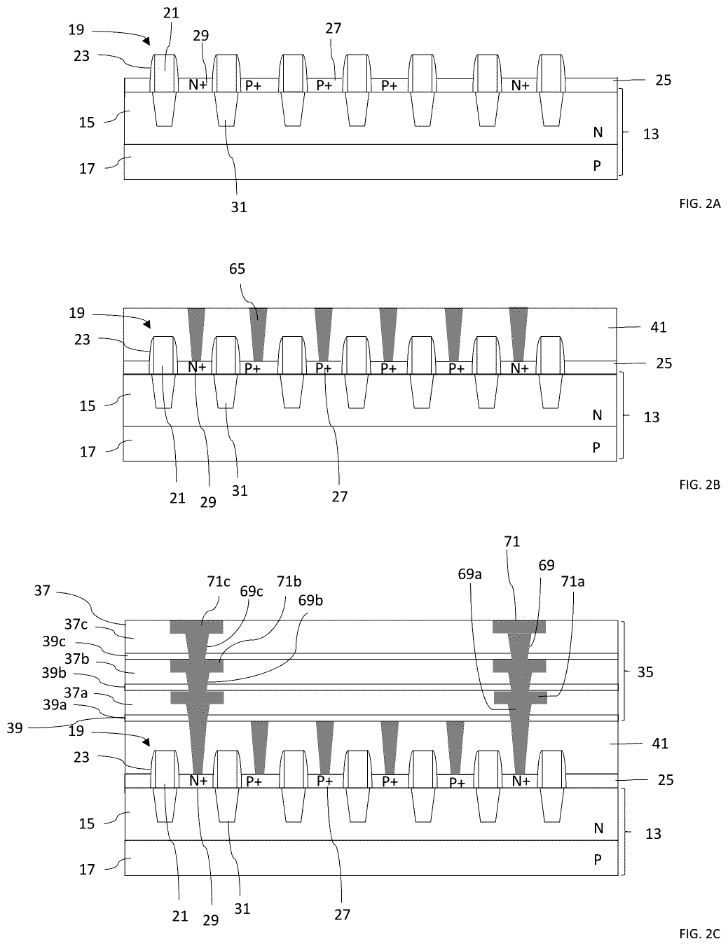

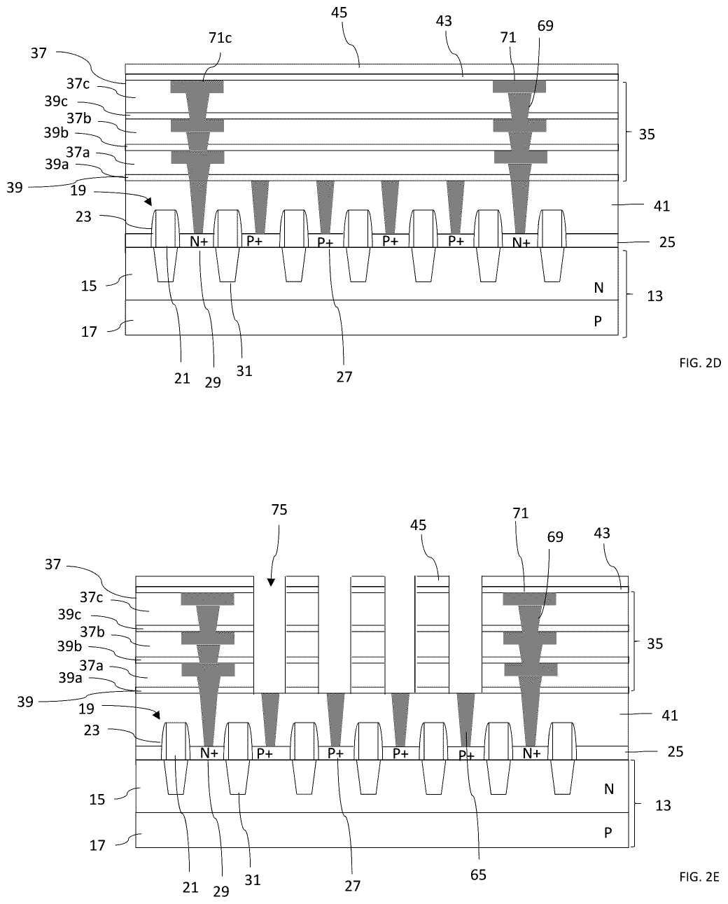

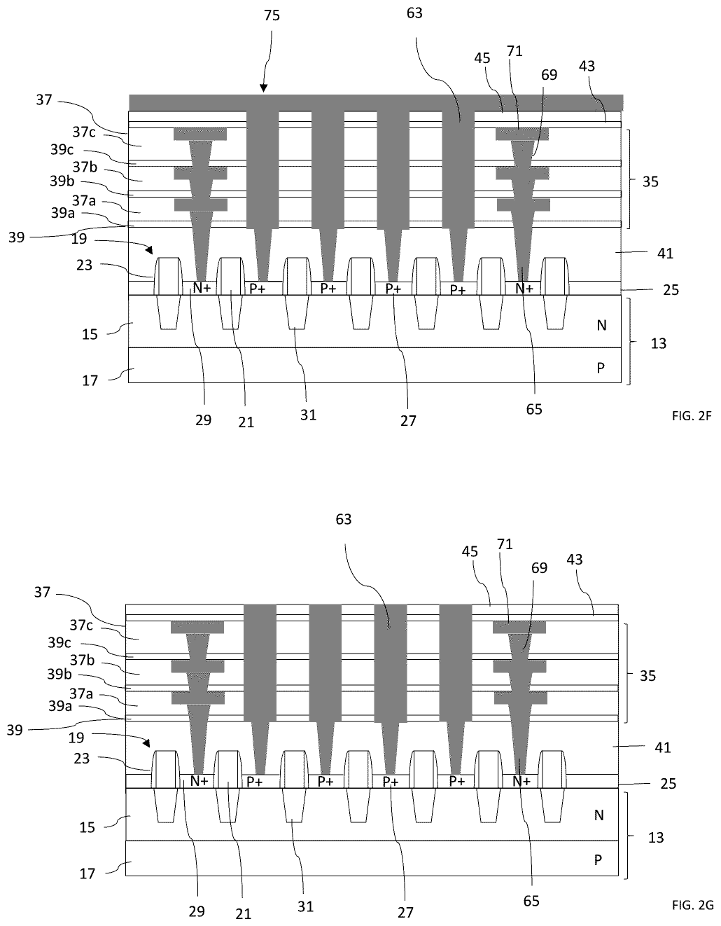

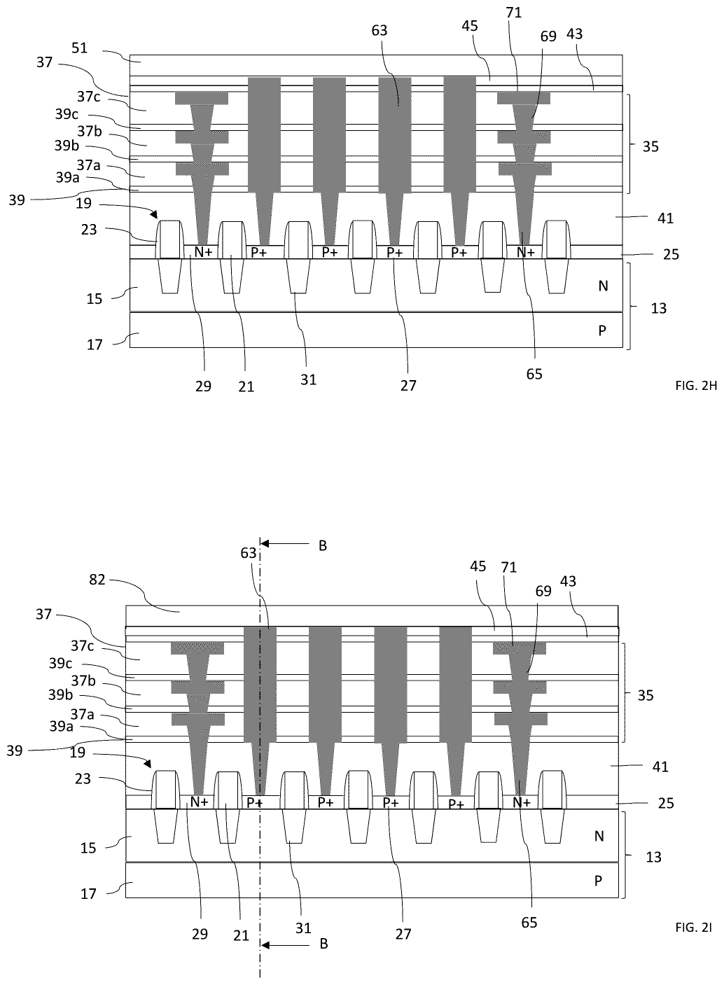

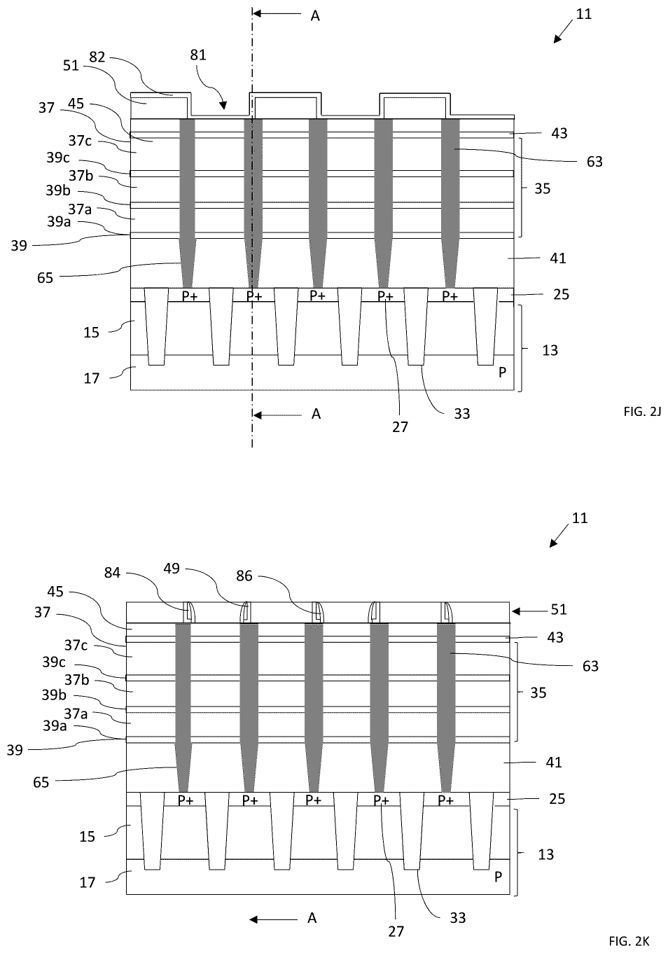

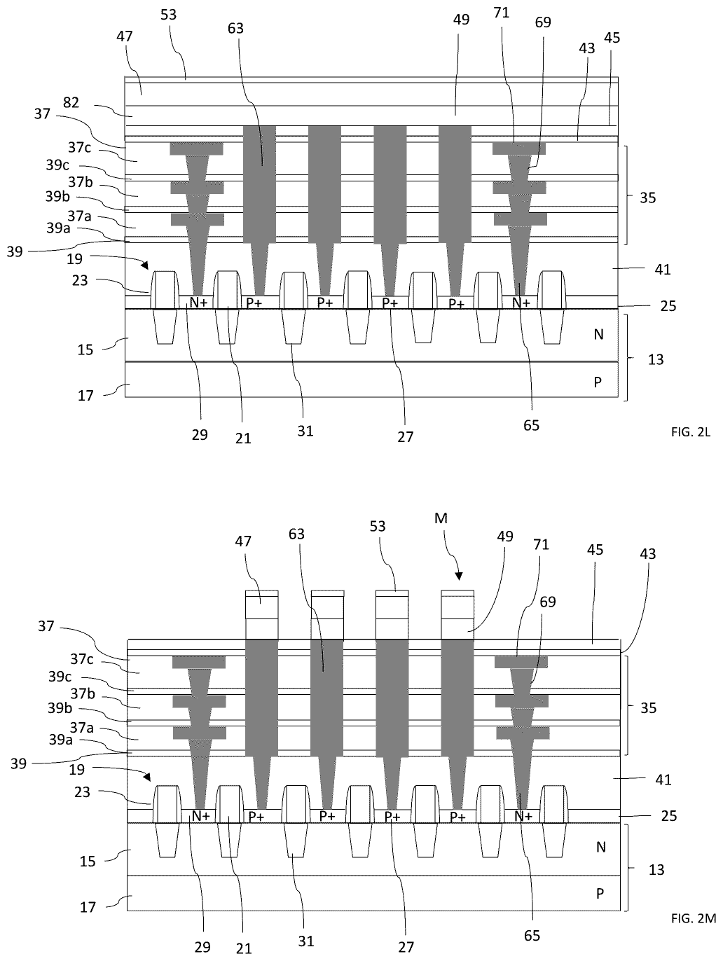

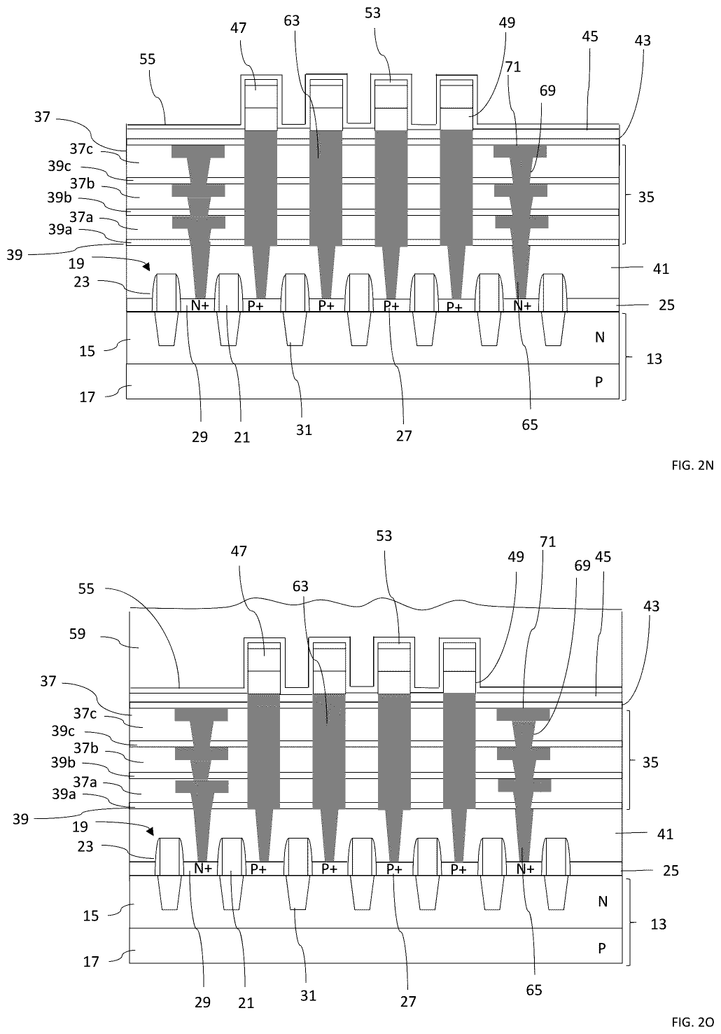

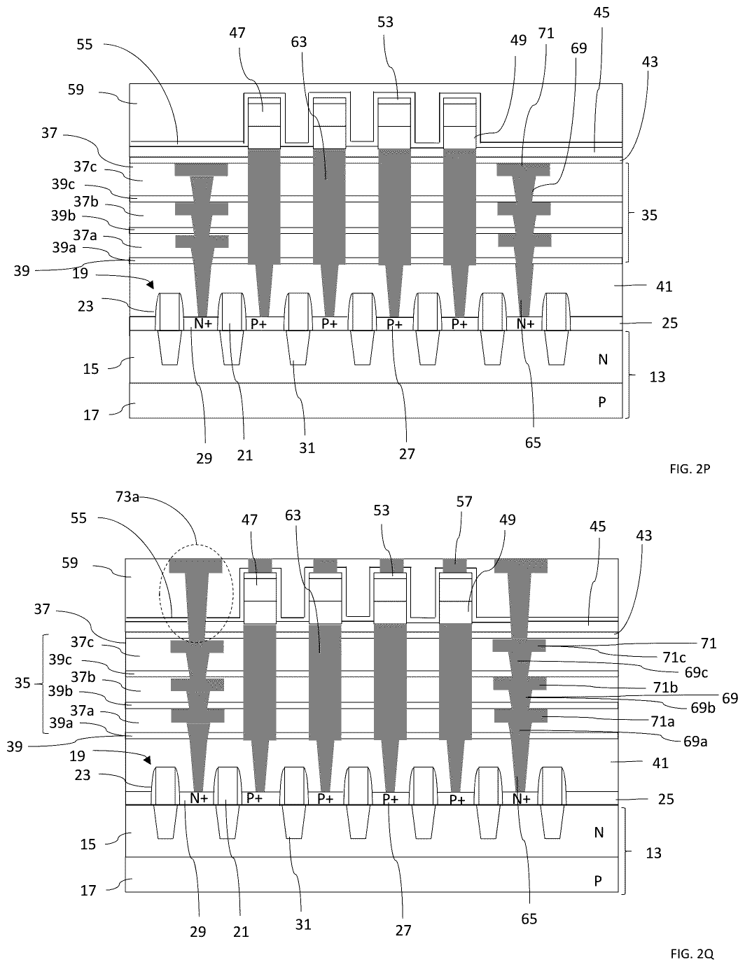

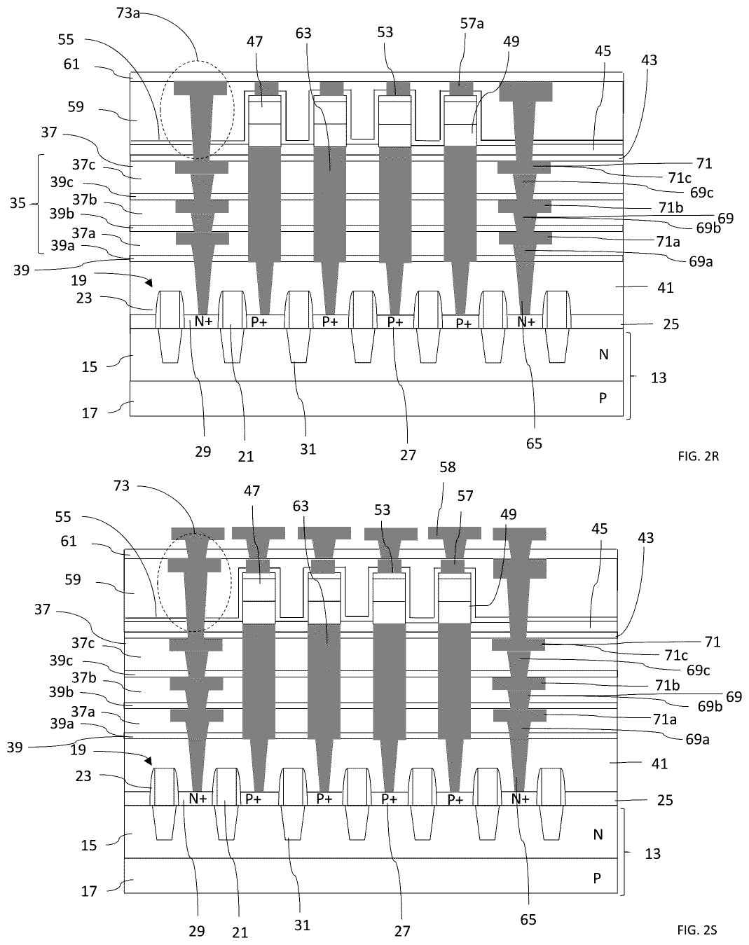

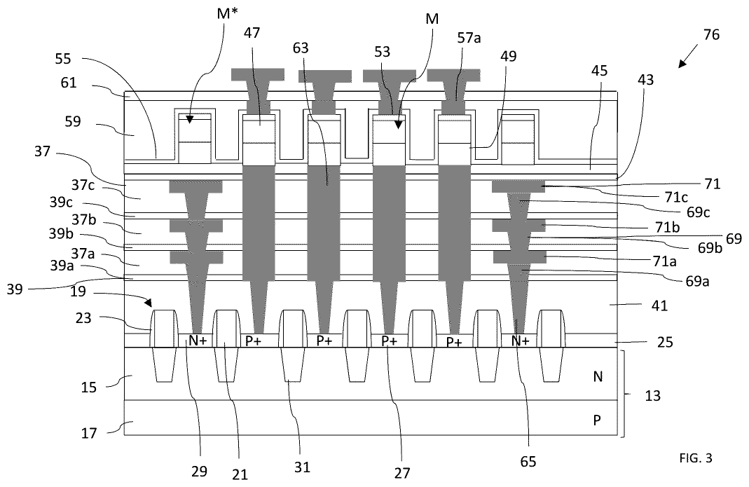

FIG. 2A, FIG. 2B, FIG. 2C, FIG. 2D, FIG. 2E, FIG. 2F, FIG. 2G, FIG. 2H, FIG. 2I, FIG. 2J, FIG. 2K, FIG. 2L, FIG. 2M, FIG. 2N, FIG. 2O, FIG. 2P, FIG. 2Q, and FIG. 2R show devices resulting from steps of an example of a method of manufacturing the electronic chip shown in FIGS. 1A and 1B.

FIG. 2A shows a cross-section view, partial and simplified, of an initial structure including on semiconductor substrate 13:
semiconductor layer 25 including regions 27 and 29; and
gate patterns 19 including a central portion 21 surrounded by spacers 23.

FIG. 2B shows a cross-section view, partial and simplified, of a structure obtained at the end of a step of forming of insulating layer 41 on the upper surface of the initial structure illustrated in FIG. 2A and of forming of vias 65 in insulating layer 41.

FIG. 2C illustrates a cross-section view, partial and simplified, of a structure obtained at the end of a step of forming of interconnection stack 35 on the upper surface of the structure illustrated in FIG. 2B and of forming of vias 69 and of conductive tracks 71 in interconnection stack 35. This step is for example carried out according to a damascene method, during which a via 69 and a conductive track 71 of a same metal level are simultaneously formed.

During this step, there is, in a first phase, formed insulating layer 39a on the upper surface of the structure illustrated in FIG. 2B, and then insulating layer 37a on the upper surface of insulating layer 39a.

Layers 39a and 37a are, in a second phase, locally etched and filled with a metallic material so as to form via 69a and conductive track 71a.

The different upper levels of interconnection stack 35 are, for example, similarly formed one after the other.

FIG. 2D illustrates a cross-section view, partial and simplified, of a structure obtained at the end of a step of forming of insulating layer 43 on the upper surface of the structure illustrated in FIG. 2C and of forming of insulating layer 45 on the upper surface of insulating layer 43. Conductive layer 43 is formed, for example, in contact with insulating layer 37c and the upper surface of conductive track 71c. As an example, insulating layer 45 is formed in contact with insulating layer 43.

FIG. 2E shows a cross-section view, partial and simplified, of a structure obtained at the end of a step of forming of openings 75 running through layers 43 and 45 and interconnection stack 35 vertically in line with regions 27. As an example, openings 75 emerge onto the upper surfaces of vias 65. Openings 75 are for example formed by etching, for example by dry etching. As an example, openings 75 are etched through an etch mask, not shown in FIG. 2E. As an example, the etch mask is made of a resin. The etch mask is, for example, deposited and structured prior to the step of etching of openings 75 by photolithography. As an example, in one embodiment, openings 75 do not have perfectly rectilinear and vertical sides. Indeed, layers 37 and 39 are of different natures and thus do not have the same etching speed. It can thus be provided for openings 75 to be wider in layers 37.

FIG. 2F illustrates a cross-section view, partial and simplified, of a structure obtained as a result of a step of deposition of a layer 77 made of the material of vias 63 on the upper surface of the structure illustrated in FIG. 2E. More particularly, during this step, layer 77 is formed so that it fully covers the upper surface of the structure illustrated in FIG. 2E and more precisely the upper surface of layer 45 and so as to fill openings 75. The vias 63 are therefore preferably entirely formed by the same cavity filling step.

FIG. 2G illustrates a cross-section view, partial and simplified, of a structure obtained as a result of a step of planarization or polishing of the upper surface of the structure illustrated in FIG. 2F, to expose the upper surface of layer 45. In other words, during this step, the excess of layer 77 is removed to only leave layer 77 in openings 75 and thus form vias 63. As an example, this step is carried out by mechanical planarization, for example by chemical mechanical planarization (CMP). As the end of this step, vias 63 are flush with the upper surface of layer 45.

FIG. 2H shows a cross-section view, partial and simplified, of a structure obtained at the end of a step of deposition of layer 51 on the upper surface of the structure illustrated in FIG. 2G. More particularly, layer 51 is formed so as to cover the entire upper surface of the structure shown in FIG. 2G. Layer 51 covers, for example, the upper surface of layer 45 and the upper surface of vias 63.

FIGS. 2I and 2J illustrate a structure obtained at the end of a step of removal of a portion of layer 51 to form openings 81 in layer 51. FIG. 2I is a cross-section view, partial and simplified, along plane A-A of FIG. 2J. FIG. 2J is a cross-section view, partial and simplified, along plane B-B of FIG. 2I.

As an example, each opening 81 extends, in cross-section plane A-A, along the entire length of the memory array. In cross-section plane B-B, each opening extends from one via 63 to the adjacent via 63. The side walls of each opening 81 are located in front of vias 63. Thus, in cross-section plane B-B, the structure includes an alternation of openings 81 and of portions of layer 51. Openings 81 preferably extend along the entire height of layer 51, so that the upper surface of vias 63 is exposed. As an example, the local removal of layer 51, to form openings 81, is carried out by etching.

The step of FIGS. 2I and 2J further includes a step of forming of a layer 82. Layer 82 is made of the material of elements 49. Layer 82 is conformally formed on the structure.

FIG. 2K illustrates a cross-section view, partial and simplified, along cross-section plane B-B, of a structure obtained at the end of a step of the method of manufacturing structure 11. During this step, first spacers 84 are formed at the side walls of openings 81. The dimensions of spacers 84 are selected to protect the portions of layer 82 forming elements 49. Spacers 84 are made of an insulating material, for example of the material of layer 51.

The step of FIG. 2K then includes the etching of the portions of layer 82 which are not protected by spacers 84. This etching for example is carried out by an anisotropic etching.

The step of FIG. 2K further includes, for example, the forming of second spacers 86 covering spacers 84 and the portions of the horizontal parts of the elements 49 exposed during the etching of layer 82. The spacers 86 are made of an insulating material, for example the material of layer 51.

The step of FIG. 2K further includes the filling of openings 81 with an insulating material, for example with the material of layer 51.

FIG. 2L shows a cross-section view, partial and simplified, of a structure obtained at the end of a step of deposition of the layer 47 of phase-change material and of metallization 53 on the upper surface of the structure illustrated in FIG. 2K. As an example, during this step, a layer of phase-change material 47 is formed on the upper surface of the structure illustrated in FIG. 2K. Layer 47 of the phase-change material is for example formed in contact with layer 49. During this step, metallization 53 is further formed on the upper surface of layer 47 of phase-change material. Metallization 53 is for example formed in contact with layer 47 of phase-change material.

FIG. 2M shows a cross-section view, partial and simplified, of a structure obtained at the end of a step of individualization of the bit lines of memory cells M in layers 47 and 49 and in metallization 53. More specifically, during this step, there is formed in front of the vias 63s of a same bit line, a stack in layers 47, 49, 51, and 82 and in metallization 53 to define the bit lines of memory cells M. As an example, at the end of this step, layer 51 remains between the heating elements 49 of a same bit line. At the end of this step, each memory cell is formed by a stack of layer 49, of layer 47, and of metallization 53. The forming of this stack after and above interconnection level 35 advantageously enables to do away with the risk of contamination of the PCM layer of the memory cell generated by the forming of the interconnection stack and of the different metal levels 71 and 69.

FIG. 2N shows a cross-section view, partial and simplified, of a structure obtained at the end of a step of deposition of layer 55 on the upper surface of the structure illustrated in FIG. 2M. More specifically, during this step, layer 55 is formed on the upper surface of layer 45 and on the upper surface and the flanks of the stacks formed in layers 47 and 49 and metallization 53, each defining a bit line of memory cells M.

FIG. 2O shows a cross-section view, partial and simplified, of a structure obtained at the end of a step of deposition of layer 59 on the upper surface of the structure illustrated in FIG. 2N. More specifically, during this step, layer 59 is for example formed so that it covers the entire layer 55. Layer 59 is for example deposited with a thickness such that the bit lines of the memory cells M defined in relation with FIG. 2M are entirely covered by layer 59.

FIG. 2P shows a cross-section view, partial and simplified, of a structure obtained at the end of a step of planarization of the upper surface of the structure illustrated in FIG. 2O. This step is for example carried out by CMP.

FIG. 2Q illustrates a cross-section view, partial and simplified, of a structure obtained at the end of a step of forming of contacts 57 and of part of the conductive vias and of the conductive tracks connecting the conductive vias 69 and the conductive tracks 71 of stack 35 to contacts 67. More specifically, the step of FIG. 2Q includes the forming of contacts 57 and of sets 73a of conductive vias and of conductive tracks running through layers 43, 45, 55, and 59. As an example, this step includes a step of etching of layers 43, 45, 55, and 59 so as to form therein openings which are then filled with the material of the conductive vias of sets 73a. Other openings are then formed in layer 59 and in layer 55, and then filled with conductive material to form the contacts 57 and the conductive tracks of sets 73a.

FIG. 2R illustrates a cross-section view, partial and simplified, of a structure obtained at the end of a step of deposition of layer 61 on the upper surface of the structure illustrated in FIG. 2Q. More specifically, during this step, layer 61 is formed on top of and in contact with the upper surface of layer 59 and the upper surfaces of the sets 73a of elements 73 and of contacts 57.

FIG. 2S shows a cross-section view, partial and simplified, of a structure obtained at the end of a step of forming of the sets 58 of conductive vias and of conductive tracks and another part of sets 73. More specifically, during this step, conductive vias and conductive tracks of a level of an interconnection network level located above layer 59 are for example formed.

The method for example includes a subsequent step, not shown, during which contact 67 is formed to result in the structure illustrated in FIGS. 1A and 1B.

FIG. 3 illustrates a cross-section view, simplified and partial, of an electronic chip 76 according to another embodiment.

Chip 76 includes the elements of chip 11 which will not be described again in detail. Chip 76 differs from chip 11 in that chip 76 does not include contacts 67 and does not include sets 73.

Thus, the regions 29 of the same row of regions 29, that is, a row extending in the direction of the bit lines including regions 29 and including no regions 27, are coupled together via vias 69 and vias 71 located in stack 35. More specifically, the regions 29 of a same row of regions 29 are coupled together via vias 69 and vias 71 located between layer 41 and layer 45. Preferably, the regions 29 of a same row of regions 29 are coupled together only by connection elements, for example vias 65, vias 69, and tracks 71, located between substrate 13 and layer 59, preferably between substrate 13 and layer 43.

The portion of layers 45 and 59 located in front of each region 29, for example, includes a dummy memory cell M*. Each cell M* includes, like a cell M, layer 47, resistive element 49, and conductive layer 53. For each memory cell M*, the upper surface of each layer 53 and the side walls of layers 47 and 53 and of element 49 are covered by layer 55.

Dummy cells M* differ from cells M in that memory cells M* are not electrically active. In other words, elements 49 and layers 53 are not electrically coupled to electronic circuits, and are not coupled to voltage application nodes. More specifically, cells M* are not electrically coupled to the tracks 71 and vias 69 of stack 35, in particular to the tracks 71 and vias 69 located between layer 43 and substrate 13. The portions of layers 43 and 45 located in front of each memory cell M* are preferably not crossed by conductive elements. Similarly, the portion of layer 55 covering layer 53 of the M* cells is preferably not crossed by a conductive element.

The method of manufacturing the embodiment of FIG. 3 is identical to the method of FIGS. 2A to 2R, except for the fact that dummy cells M* are preferably formed simultaneously to cells M.

Although FIG. 3 includes, in the word line direction, groups of four M memory cells separated from one another by a memory cell M*, in one embodiment the groups include any number of cells M, for example more than four cells M.

An advantage of the present embodiment is that it enables to do away with metal level sizing constraints for PCM cell integration, since the surface area of vias 63 can be smaller than the surface area of a track 71 at the surface of interconnection stack 35. This embodiment advantageously includes no vias 69 and tracks 71.

Another advantage of the present embodiment is that the forming of the memory cells above interconnection level 35 enables to do away with risks of contamination of the PCM layer of the memory cell generated by the forming of the interconnection stack and of the various metal levels 71 and 69.

Still another advantage of the present embodiment is that it is compatible with known methods and logic parts, the logic part not being impacted.

An advantage of the embodiment of FIG. 3 is that the presence of dummy memory cells enables to ensure that the forming of memory cells in the layer is regular. This enables to avoid manufacturing variations between memory cells.

Various embodiments and variants have been described. Those skilled in the art will understand that certain features of these various embodiments and variants may be combined, and other variants will occur to those skilled in the art. In particular, although the memory circuit has been described for memory cells including a phase-change material, it may be provided for this memory circuit to be able to apply to other types of memory cells.

Finally, the practical implementation of the described embodiments and variants is within the abilities of those skilled in the art based on the functional indications given hereabove.

In one embodiment, an electronic chip (11) includes a memory circuit including: a semiconductor substrate (13) having selection transistors arranged therein; an interconnection stack (35), arranged on the semiconductor substrate (13), including a succession of levels, each level including a first insulating layer (37) and a second insulating layer (39), having interconnection elements (71, 69) defined therein; and a plurality of memory cells (M) arranged above the interconnection stack (35), each memory cell (M) being adapted to being electrically coupled to a selection transistor via a first conductive via (63) running through the entire thickness of the interconnection stack (35).

In one embodiment, the semiconductor substrate (13) includes, from an upper surface, a first doped semiconductor layer (15) of a first conductivity type (N), located on top of and in contact with a second doped semiconductor layer (17) of a second conductivity type (P) opposite to the first conductivity type.

In one embodiment, the semiconductor substrate (13) is topped with a third semiconductor layer (25) including first doped regions (27) of the second conductivity type (P), each of the first regions of the third semiconductor layer being coupled to a memory cell (M) via the first conductive via (63).

In one embodiment, the first semiconductor layer (15), the second semiconductor layer (17), and the first regions (27) of the third semiconductor layer (25) form the selection transistors.

In one embodiment, the third semiconductor layer (25) includes second doped regions (29) of the first conductivity type (N), each of the second regions (29) of the third semiconductor layer (25) being coupled to a set of second conductive vias (69) and of conductive tracks (71) running through the interconnection stack (35).

In one embodiment, the second conductive vias (69) and the conductive tracks (71) are made of copper.

In one embodiment, the conductive tracks (71) laterally extend over a surface area greater than the surface area of the first conductive via (63).

In one embodiment, at least two second regions (29) are coupled to each other by a set of second conductive vias (69) and of conductive tracks (71) located in the interconnection stack (35) between the substrate (13) and the memory cells.

In one embodiment, the chip includes dummy memory cells located in front of the second regions (29).

In one embodiment, the first conductive via (63) is made of a metallic material.

In one embodiment, the first conductive via (63) is made of tungsten, of cobalt, or of copper.

In one embodiment, a method of manufacturing an electronic chip includes a memory circuit, including the following successive steps: a) forming selection transistors in a semiconductor substrate (13); b) forming an interconnection stack (35), arranged on the semiconductor substrate (13), including a succession of levels, each level including an alternation of first insulating layers (37) and of second insulating layers (39) having interconnection elements defined therein; and c) forming a plurality of memory cells (M) arranged above the interconnection stack (35), each memory cell (M) being electrically coupled to a selection transistor via a first conductive via (63) running through the entire thickness of the interconnection stack (35).

In one embodiment, the first conductive via (63) is formed between steps b) and c).

In one embodiment, the step of forming of the first conductive vias (63) includes a step of etching of the interconnection stack (35) so as to form openings (75) and a step of filling of the openings (75).

In one embodiment, the step of etching of the interconnection stack (35) corresponds to a step of etching of all the first insulating layers (37) and of second insulating layers (39) of the interconnection stack (35).

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic chip comprising a memory circuit including:
a semiconductor substrate having a plurality of selection transistors arranged therein;
an interconnection stack on the semiconductor substrate and including a succession of levels, each level including:
a first insulating layer;
a second insulating layer; and
a plurality of interconnection elements in the first and second insulating layers; and
a plurality of memory cells arranged above the interconnection stack, each memory cell being configured to being electrically coupled to a selection transistor via a first conductive via running through the entire thickness of the interconnection stack.

2. The electronic chip according to claim 1, wherein the semiconductor substrate includes, from an upper surface, a first doped semiconductor layer of a first conductivity type, located on top of and in contact with a second doped semiconductor layer of a second conductivity type opposite to the first conductivity type.

3. The electronic chip according to claim 1, wherein the semiconductor substrate is topped with a third semiconductor layer including first doped regions of the second conductivity type, each of the first regions of the third semiconductor layer being coupled to a memory cell via the first conductive via.

4. The electronic chip according to claim 2, wherein the first semiconductor layer, the second semiconductor layer, and the first regions of the third semiconductor layer form the selection transistors.

5. The electronic chip according to claim 3, wherein the third semiconductor layer includes second doped regions of the first conductivity type, each of the second regions of the third semiconductor layer being coupled to a set of second conductive vias and of conductive tracks running through the interconnection stack.

6. The electronic chip according to claim 5, wherein the second conductive vias and the conductive tracks are made of copper.

7. The electronic chip according to claim 5, wherein the conductive tracks laterally extend over a surface area greater than the surface area of the first conductive via.

8. The electronic chip according to claim 5, wherein at least two second regions are coupled to each other by a set of second conductive vias and of conductive tracks located in the interconnection stack between the substrate and the memory cells.

9. The electronic chip according to claim 8, wherein the chip includes dummy memory cells located in front of the second regions.

10. The electronic chip according to claim 1, wherein the first conductive via is made of a metallic material.

11. The electronic chip according to claim 10, wherein the first conductive via is made of tungsten, of cobalt, or of copper.

12. The electronic chip according to claim 1, comprising a first portion and a second portion, the first portion including a memory circuit, the second portion including a logic circuit, the first portion including the plurality of memory cells, wherein the second portion does not include a first via.

13. The electronic chip according to claim 1, wherein each first via is a single piece via.

14. A method of manufacturing an electronic chip including a memory circuit, the method comprising:
forming selection transistors in a semiconductor substrate;
forming an interconnection stack, arranged on the semiconductor substrate, including a succession of levels, each level including an alternation of first insulating layers and of second insulating layers having interconnection elements defined therein; and
forming a plurality of memory cells arranged above the interconnection stack, each memory cell being electrically coupled to a selection transistor via a first conductive via running through the entire thickness of the interconnection stack.

15. The method according to claim 14, wherein the first conductive via is formed before forming the plurality of memory cells and after forming the interconnection stack.

16. The method according to claim 15, wherein forming the first conductive vias includes:
etching the interconnection stack to form openings; and
filling the openings.

17. The method according to claim 16, wherein the step of etching of the interconnection stack includes etching all the first insulating layers and the second insulating layers of the interconnection stack.

18. A method, comprising:
forming a plurality of selection transistors;
forming a first pair of dielectric layers above the selection transistors;
forming a second pair of dielectric layers above the first pair of dielectric layers;
forming a metal interconnect structure extending through the first and second pairs of dielectric layers and electrically coupled to a first selection transistor of the plurality of selection transistors;
forming, after forming the metal interconnect structure, a first conductive via extending through the first and second pairs of dielectric layers and electrically coupled to a second selection transistor of the plurality of selection transistors; and
forming a first memory cell on the conductive via.

19. The method of claim 18, wherein the first memory cell is a phase change memory cell.

20. The method of claim 18, wherein the metal interconnect structure includes at least one conductive track and at least a second conductive via.

21. The method of claim 18, comprising forming an insulating layer on the transistors prior to forming the first pair of dielectric layers.
